(19) United States
(12) Patent Application Publication
(10) Pub. No.: US 2018/0375048 A1
(43) Pub. Date: Dec. 27, 2018

(54) LIGHT-EMITTING DIODE AND DISPLAY DEVICE INCLUDING THE SAME

(71) Applicant: SAMSUNG DISPLAY CO., LTD., YONGIN-SI (KR)

(72) Inventors: Dong Chan KIM, Gunpo-si (KR); Won Jong KIM, Suwon-si (KR); Ji Young MOON, Gwangju-si (KR); Yeong Rong PARK, Osan-si (KR); Dong Kyu SEO, Suwon-si (KR); Myung Chul YEO, Asan-si (KR); Ji Hye LEE, lncheon (KR); Yoon Hyeung CHO, Yongin-si (KR)

(21) Appl. No.: 15/864,671

(22) Filed: Jan. 8, 2018

(30) Foreign Application Priority Data
Jun. 21, 2017 (KR) 10-2017-0078678

(51) Int. Cl. H01L 51/50; H01L 51/00; H01L 51/52; C09K 11/06

(52) U.S. Cl. CPC H01L 51/506; H01L 51/0059; C09K 2211/1007; C09K 11/06; H01L 51/5203

(57) ABSTRACT

A light-emitting diode includes a first electrode, a second electrode, a light-emitting layer, and a hole transfer layer. The light-emitting layer is disposed between the first electrode and the second electrode. The hole transfer layer is disposed between the light-emitting layer and the second electrode. The hole transfer layer includes an organic material. At least one of tellurium or a telluride compound of a transition metal is doped in the organic material included in the hole transfer layer.

### CROSS-REFERENCE TO RELATED APPLICATION

This application claims priority under 35 U.S.C. § 119 to Korean Patent Application No. 10-2017-0078678, filed on Jun. 21, 2017 in the Korean Intellectual Property Office, the disclosure of which is incorporated herein by reference in its entirety.

### TECHNICAL FIELD

Exemplary embodiments of the present invention relate to a light-emitting diode, and more particularly to a display device including the same.

### DISCUSSION OF RELATED ART

An organic light-emitting diode display device may be a self-light emitting display device. Organic light-emitting diode display devices may have a relatively large viewing angle, a relatively high contrast, and a relatively fast response time.

The organic light-emitting diode display device may include an organic light-emitting diode, for example, for emitting light. The organic light-emitting diode may form a plurality of excitons, for example, by coupling a plurality of electrons injected from a first electrode with a plurality of holes injected from a second electrode in a light-emitting layer. The plurality of excitons may emit energy by falling from an excited state to a ground state. Thus, light may be emitted.

In order to increase efficiency of the organic light-emitting diode, an injection speed of the plurality of holes and the plurality of electrons may be increased.

### SUMMARY

Exemplary embodiments of the present invention provide a light-emitting diode. The light-emitting diode includes a first electrode, a second electrode, a light-emitting layer, and a hole transfer layer. The light-emitting layer is disposed between the first electrode and the second electrode. The hole transfer layer is disposed between the light-emitting layer and the second electrode. The hole transfer layer includes an organic material. At least one of tellurium or a telluride compound of a transition metal is doped in the organic material of the hole transfer layer.

In the hole transfer layer, a doped content of the at least one of the tellurium or the telluride compound of the transition metal may be in a range of from about 1 vol % to about 10 vol %.

The telluride compound of the transition metal may be at least one selected from ZnTe, NiTe, PdTe, PtTe, CoTe, RhTe, IrTe, FeTe, RuTe, IrTe, FeTe, RuTe, OsTe, MnTe, TcTe, ReTe, Cu2Te, CuTe, Ag₂Te AgTe, Au₂Te, Cr₂Te₃, Mo₂Te₃, W₂Te₃, V₂Te₃, Nb₂Te₃, Ta₂Te₃, TiTe₂, ZrTe₂, HfTe₂, Li₂Te, Na₂Te, K₂Te, Rb₂Te, Cs₂Te, BeTe, MgTe, CaTe, SrTe, BaTe, LaTe, CeTe, PrTe, NdTe, PmTe, EuTe, GdTe, TbTe, DyTe, HoTe, ErTe, TmTe, YbTe, Bi₂Te₃ or LuTe.

The organic material of the hole transfer layer may include a compound represented by Chemical Formula 1 below:

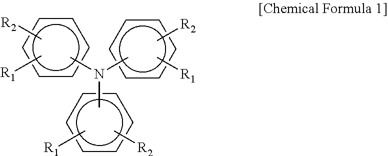

R₁ and R₂ may each be independently selected from a substituted or unsubstituted C₃-C₁₀ cycloalkyl group, a substituted or unsubstituted C₂-C₂₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₂-C₆₀ heteroaryl group, a substituted or unsubstituted monovalent non-aromatic condensed polycyclic group, or a substituted or unsubstituted monovalent non-aromatic hetero-condensed polycyclic group.

The light-emitting diode may further include an electron transfer layer. The electron transfer layer may be disposed between the first electrode and the light-emitting layer. The electron transfer layer may include an alkali halide doped in a lanthanide metal or an alkaline earth metal.

The lanthanide metal may be at least one selected from La, Ce, Pr, Nd, Pm, Sm, Eu, Gd, Tb, Dy, Ho, Er, Tm, Yb or Lu. The alkali earth metal may be at least one selected from Mg, Ca, Sr, Ba or Ra. The alkali halide may be at least one selected from LiCl, NaCl, KCl, RbCl, CsCl, FrCl, LiBr, NaBr, KBr, RbBr, CsBr, FrBr, LiI, NaI, KI, RbI, CsI or FrI.

The electron transfer layer may include an electron transport layer and an electron injection layer. The electron transport layer may be disposed between the light-emitting layer and the first electrode. The electron injection layer may be disposed between the elects on transport layer and the first electrode. The electron transport layer may include an alkali halide doped in a lanthanide metal or an alkaline earth metal.

The hole transfer layer may include a hole injection layer and a hole transport layer. The hole injection layer may be disposed between the second electrode and the hole transport layer. The hole transport layer may be disposed between the hole injection layer and the light-emitting layer.

Exemplary embodiments of the present invention provide a light-emitting diode. The light-emitting diode includes a first electrode, a second electrode, a light-emitting layer, a hole transfer layer, and a hole auxiliary layer. The second electrode overlaps the first electrode. The light-emitting layer is disposed between the first electrode and the second electrode. The hole transfer layer is disposed between the light-emitting layer and the second electrode. The hole auxiliary layer is disposed in at least one of between the hole transfer layer and the light-emitting layer or between the hole transfer layer and the second electrode. The hole auxiliary layer includes at least one of tellurium or a telluride compound of a transition metal.

A thickness of the hole auxiliary layer may be in a range of from about 5Ω to about 30Ω.

The telluride compound of the transition metal may be at least one selected from ZnTe, NiTe, PdTe, PtTe, CoTe, RhTe, IrTe, FeTe, RuTe, IrTe, FeTe, RuTe, OsTe, MnTe, TcTe, ReTe, Cu2Te, CuTe Ag₂Te, AgTe, Au₂Te, Cr₂Te₃, Mo₂Te₃, W₂Te₃, V₂Te₃, Nb₂Te₃, Ta₂Te₃, TiTe₂, ZrTe₂, HfTe₂, Li₂Te, Na₂Te, K₂Te, Rb₂Te, Cs₂Te, BeTe, MgTe, CaTe, SrTe, BaTe, LaTe, CeTe, PrTe, NdTe, PmTe, EuTe, GdTe, TbTe, DyTe, HoTe, ErTe, TmTe, YbTe, Bi₂Te₃ or LuTe.

The light-emitting diode may further include an electron transfer layer. The electron transfer layer may be disposed between the first electrode and the light-emitting layer. The electron transfer layer may include an alkali halide doped in a lanthanide metal or an alkaline earth metal.

The lanthanide metal may be at least one selected from La, Ce, Pr, Nd, Pm, Sm, Eu, Gd, Tb, Dy, Ho, Er, Tm, Yb or Lu. The alkali earth metal may be at least one selected from Mg, Ca, Sr, Ba or Ra. The alkali halide may be at least one selected from LiCl, NaCl, KCl, RbCl, CsCl, FrCl, LiBr, NaBr, KBr, RbBr, CsBr, FrBr, LiI, NaI, KI, RbI, CsI or FrI.

The electron transfer layer may include an electron transport layer and an electron injection layer. The electron transport layer may be disposed between the light-emitting layer and the first electrode. The electron injection layer may be disposed between the electron transport layer and the first electrode. The electron transport layer may include an alkali halide doped in a lanthanide metal or an alkaline earth metal.

The hole auxiliary layer might not include an organic material.

The hole auxiliary layers may be disposed between the hole transfer layer and the light-emitting layer, and between the hole transfer layer and the second electrode.

Exemplary embodiments of the present invention provide a light-emitting diode. The light-emitting diode includes a first electrode, a second electrode, a light-emitting layer, and a hole transfer layer. The second electrode overlaps the first electrode. The light-emitting layer is disposed between the first electrode and the second electrode. The hole transfer layer is disposed between the light-emitting layer and the second electrode. The hole transfer layer includes an inorganic material. At least one of tellurium or a telluride compound of a transition metal is doped in the inorganic material included in the hole transfer layer.

The inorganic material may include a material having a band gap of about 3.2 eV or more.

The inorganic material may be at least one of NaI, KI, RbI, CsI, MgI₂, CaI₂, SrI₂, or BaI₂.

The tellurium or the telluride compound of the transition metal may be at least one selected from Te, ZnTe, or CoTe. A doped content of the at least one of the tellurium or the telluride compound of the transition metal may be in a range of from about 1 vol % to about 50 vol %.

### BRIEF DESCRIPTION OF THE DRAWINGS

The above and other features of the present invention will become more apparent by describing in detail exemplary embodiments thereof, with reference to the accompanying drawings, in which:

FIG. 1 is a cross-sectional view illustrating a light-emitting diode according to an exemplary embodiment of the present invention;

FIG. 2 is a cross-sectional view illustrating a light-emitting diode according to an exemplary embodiment of the present invention;

FIG. 3 is a cross-sectional view illustrating a light-emitting diode according to an exemplary embodiment of the present invention;

FIG. 4 is a cross-sectional view illustrating a light-emitting diode according to an exemplary embodiment of the present invention; and

FIG. 5 is a cross-sectional view illustrating a display device according to an exemplary embodiment of the present invention.

### DETAILED DESCRIPTION OF THE EMBODIMENTS

Exemplary embodiments of the present invention will be described below in more detail with reference to the accompanying drawings. In this regard, the exemplary embodiments may have different forms and should not be construed as being limited to the exemplary embodiments of the present invention described herein.

Like reference numerals may refer to like elements throughout the specification and drawings.

It will be understood that although the terms “first” and “second” may be used herein to describe various components, these components should not be limited by these terms.

Sizes of elements in the drawings may be exaggerated for clarity of description.

It will be understood that when a component, such as a layer, a film, a region, or a plate, is referred to as being “on” another component, the component can be directly on the other component or intervening components may be present.

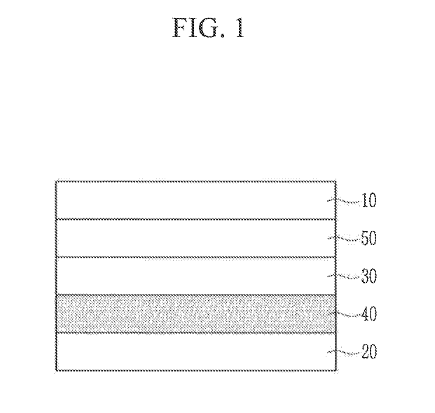

FIG. 1 is a cross-sectional view illustrating a light-emitting diode according to an exemplary embodiment of the present invention.

Referring to FIG. 1, a light-emitting diode according to an exemplary embodiment of the present invention may include a first electrode 10, a second electrode 20, and a light-emitting layer 30. The first electrode 10 may at least partially overlap the second electrode 20. For example, the first electrode 10 may entirely overlap the second electrode 20. The light-emitting layer 30 may be disposed between the first electrode 10 and the second electrode 20. The light-emitting diode may also include a hole transfer layer 40 and an electron transfer layer 50. The hole transfer layer 40 may be disposed between the second electrode 20 and the light-emitting layer 30. The electron transfer layer 50 may be disposed between the first electrode 10 and the light-emitting layer 30.

The hole transfer layer 40 may include at least one of a hole transport layer (HTL) and a hole injection layer (HIL). Thus, the hole transfer layer 40 may include the hole transport layer (HTL) and the hole injection layer (HIL). The hole injection layer (HIL) may be positioned to be adjacent to the second electrode 20. The hole transport layer (HTL) may be positioned to be adjacent to the light-emitting layer 30. For example, the light-emitting layer 30 may be disposed on the hole transport layer (HTL); the hole transport layer (HTL) may be disposed on the hole injection layer (HIL); and the hole injection layer (HIL) may be disposed on the second electrode 20; however, exemplary embodiments of the present invention are not limited thereto.

The hole transfer layer 40 may include an organic material. The hole transfer layer 40 may also include at least one of tellurium doped in the organic material or a telluride compound of a transition metal doped in the organic material. The organic material of the hole transfer layer 40 may include a compound represented by Chemical Formula 1 below.

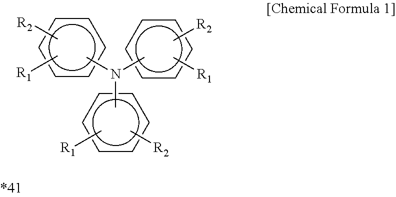

R₁ and R₂ may each independently be selected from a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₂-C₆₀ heteroaryl group, a substituted or unsubstituted monovalent non-aromatic condensed polycyclic group, or a substituted or unsubstituted monovalent non-aromatic hetero-condensed polycyclic group.

Further, according to an exemplary embodiment of the present invention, the Ar₁ and Ar₂ of Chemical Formula 1 may each independently be selected from a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenarithrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dihenzofuranyl group, a dibenzothiophenyl group, a benzocarbarzolyl group, a dibenzocarbarzolyl group, a thiadiazolyl group, an imidazopyridinyl group, and an imidazolopyrimidinyl group; and a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicentyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbarzolyl group, a dibenzocarbarzolyl group, a thiadiazolyl group, an imidazopyridinyl group, and an imidazolopyrimidinyl group, which are substituted with at least one of deuterium, —F, —Cl, —Br, —I, a hydroxyl group, a cyano group, a nitro group, an amino group, an amidino group, a hydrazine group, a hydrazone group, carboxylic acid or a salt thereof, sulfonic acid or a salt thereof, phosphoric acid or a salt thereof, a C₂-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbarzolyl group, a dibenzocarbarzolyl group, a thiadiazolyl group, an imidazopyridinyl group, an imidazolopyrimidinyl group, —Si(Q₃₁)(Q₃₂)(Q₃₃), —B(Q₃₄)(Q₃₅) or —N(Q₃₆)(Q₃₇).

A doping amount of tellurium and/or the telluride compound of the transition metal which is doped in the hole transfer layer 40 may be in a range of from about 1 vol % to about 10 vol %. Further, the telluride compound of the transition metal may be one selected from ZnTe, NiTe, PdTe, PtTe, CoTe, RhTe, IrTe, FeTe, RuTe, IrTe, FeTe, RuTe, OsTe, MnTe, TcTe, ReTe, Cu2Te, CuTe, Ag₂Te, AgTe, Au₂Te, Cr₂Te₃, Mo₂Te₃, W₂Te₃, V₂Te₃, Nb₂Te₃, Ta₂Te₃, TiTe₂, ZrTe₂, HfTe₂, Li₂Te, Na₂Te, K₂Te, Rb₂Te, Cs₂Te, BeTe, MgTe, CaTe, SrTe, BaTe, LaTe, CeTe, PrTe, NdTe, PmTe, EuTe, GdTe, TbTe, DyTe, HoTe, ErTe, TmTe, YbTe, Bi₂Te₃ or LuTe; and at least one thereof may be included in the hole transfer layer 40.

The organic material and the telluride compound of the transition metal may form a charge transfer complex.

According to an exemplary embodiment of the present invention, the hole injection layer (HIL) of the hole transfer layer 40 may include an organic material. The hole injection layer (HIL) of the hole transfer layer 40 may also include at least one of tellurium doped in the organic material or a telluride compound of a transition metal doped in the organic material. A hole auxiliary layer may be disposed between the hole transport layer (HTL) and the light-emitting layer 30. Alternatively, the hole auxiliary layer may be disposed between the hole transport layer (HTL) and the second electrode 20. The hole auxiliary layer may include at least one of tellurium, a telluride compound of a transition metal, tellurium doped in the organic material, or a telluride compound of a transition metal doped in the organic material.

According to an exemplary embodiment of the present invention, when the hole transfer layer 40 includes an organic material, and tellurium doped in the organic material or a telluride compound of a transition metal, increased efficiency of hole transport and emissions may be provided. Further, due to a relatively low band gap and a relatively high conductivity of tellurium or the telluride compound of a transition metal, doping properties may be increased and a process time and a manufacturing cost may be reduced.

The hole transfer layer 40 may include an inorganic material and tellurium or a telluride compound of a transition metal doped in the inorganic material. Due to a relatively low band gap and a relatively high conductivity of the tellurium or the telluride, compound of a transition metal, doping properties may be increased and a process time and a manufacturing cost may be reduced.

The inorganic material may include a material having a band gap of about 3.2 eV or more (e.g., among alkali halides or alkaline earth metal halides). For example, the inorganic material may include a material having a band gap of about 3.2 eV or more among iodine compounds of alkali metals or iodine compounds of alkaline earth metals.

For example, the inorganic material may be at least one of NaI, KI, RbI, CsI, MgI₂, CaI₂, SrI₂, or BaI₂. Further, the tellurium or the tellurium and the telluride compound of a transition metal may be at least one of Te, ZnTe or CoTe. The doped content of the tellurium or the tellurium and the telluride compound of a transition metal may be in the range of from about 1 vol % to about 50 vol %.

According to an exemplary embodiment of the present invention, the first electrode 10 may be a cathode, and the second electrode 20 may be an anode. The first electrode 10 may be an electrode which injects a plurality of electrons into the light-emitting layer 30, for example, when receiving a current. The first electrode 10 may include a material having a relatively low work function. The second electrode 20 may be an anode which injects a plurality of holes into the light-emitting layer 30, for example, when receiving a current. The second electrode 20 may include a material having a relatively high work function. However, exemplary embodiments of the present invention are not limited thereto. For example, the first electrode 10 may be an anode, and the second electrode 20 may be a cathode.

The first electrode 10 and the second electrode 20 may each include a conductive oxide such as indium tin oxide (ITO), indium zinc oxide (IZO), zinc tin oxide (ZTO), copper indium oxide (CIO), copper zinc oxide (CZO), gallium zinc oxide (GZO), aluminum zinc oxide (AZO), tin oxide (SnO₂), zinc oxide (ZnO) or combinations thereof, calcium (Ca), ytterbium (Yb), aluminum. (Al), silver (Ag), magnesium (Mg), samarium (Sm), titanium (Ti), gold (Au), or alloys thereof. The first electrode 10 and the second electrode 20 may each include a conductive polymer such as graphene, carbon nanotube or PEDOT:PSS. However, the first electrode 10 and the second electrode 20 are not limited thereto. For example, the first electrode 10 and the second electrode 20 may also have a laminated structure including two or more layers.

Further, according to an exemplary embodiment of the present invention, the first electrode 10 may include an alloy including two or more materials selected from Ag, Mg, Al or Yb. The first electrode 10 may include AgMg. When the first electrode 10 includes AgMg, an amount of silver (Ag) of the first electrode 10 may be larger than an amount of magnesium (Mg) of the first electrode 10. For example, the content of magnesium (Mg) may be about 10 vol %. A thickness of the first electrode 10 may be in a range of from about 80Ω to about 100Ω. The first electrode 10 may include AgYb. When the first electrode 10 includes AgYb, an amount of ytterbium (Yb) may be about 10 vol %. However exemplary embodiments of the present invention are not limited thereto.

According to an exemplary embodiment of the present invention, the second electrode 20 may be a reflective electrode. The reflective electrode may have a structure of ITO/Ag/ITO. The first electrode 10 may be a semi-transmissive electrode. The semi-transmissive electrode may include AgMg. Light generated in the light-emitting layer 30 may be reflected, for example, by the second electrode 20 as a reflective electrode, and may be resonated and amplified between the first electrode 10 as the semi-transmissive electrode and the second electrode 20. The resonated light may be reflected by the second electrode 20 and emitted to an upper surface of the first electrode 10.

The light-emitting layer 30 may include a light-emitting host and light-emitting dopant. A composition of the dopant may vary, for example, depending on a material included in the light-emitting layer. The dopant may be 3 to 10 parts by weight based on 100 parts by weight of a material for forming the light emitting layer (e.g., the total weight of the host and the dopant).

The host material of the light-emitting layer may include tris(8-hydroxy-quinolinato)aluminium (Alq₃), 9,10-di(2-naphthy-2-yl)anthracene (ADN), 3-tert-butyl-9,10-di(naphthy-2-yl)anthracene (TBADN), 4,4′-bis(2,2-diphenyl-ethene-1-yl)-4,4′-dimethylphenyl (DPVBi), 4,4′-bis(2,2-diphenyl-ethene-1-yl)-4,4′-methylphenyl (p-DMDPVBi), tert(9,9-diarylfluorene) (TDAF), 2-(9,9′-spirobifluoren-2-yl)-9,9′-spirobifluorene (BSDF), 2,7-bis(9,9′-spirobifluoren-2-yl)-9,9′-spirobifluorene (TSDF), bis(9,9-diarylfluorene) (BDAF), 4,4′-bis(2,2-diphenyl-ethene-1-yl)-4,4′-di-(tert-butyl) phenyl (p-TDPVBi), or the like. The phosphorescent host material may include 1,3-bis(carbazol-9-yl) benzene (mCP), 1,3,5-tris(carbazol-9-yl) benzene (tCP), 4,4′,4″-tris(carbazol-9-yl) triphenylamine (TcTa), 4,4′-bis(carbazol-9-yl) biphenyl (CBP), 4,4′-bis(9-carbazolyl)-2,2′-dimethyl-biphenyl (CBDP), 4,4′-bis(carbazol-9-yl)-9,9-dimethyl-fluorene (DMFL-CBP), 4,4′-bis(carbazol-9-yl)-9,9-bis(9-phenyl-9H-carbazol) fluorine (FL-4CBP), 4,4′-bis(carbazol-9-yl)-9,9-di-tolyl-fluorene (DPFL-CBP), or 9,9-bis (9-phenyl-9H-carbazol) fluorine (FL-2CBP).

The dopant may include complexes of 8-hydroxyquinoline or benzazole derivatives; however, exemplary embodiments of the present invention are not limited thereto.

The light-emitting layer 30 may include quantum dots.

The electron transfer layer 50 may be disposed between the light-emitting layer 30 and the first electrode 10. The electron transfer layer 50 may include an alkali halide doped in a lanthanide metal or an alkaline earth metal. The electron transfer layer 50 may include an electron transport layer (ETL) and an electron injection layer (EIL). The electron injection layer (EIL) may be positioned to be adjacent to the first electrode 10. The electron transport layer (ETL) may be positioned to be adjacent to the light-emitting layer 30. In the electron transfer layer 50, the lanthanide metal may be one selected from La, Ce, Pr, Nd, Pm, Sm, Eu, Gd, Tb, Dy, Ho, Er, Tm, Yb or Lu. The alkali earth metal may be one selected from Mg, Ca, Sr, Ba or Ra. The alkali halide may be one selected from LiCl, NaCl, KCl, RbCl, CsCl, FrCl, LiBr, NaBr, KBr, RbBr, CsBr, FrBr, LiI, NaI, KI, RbI, CsI or FrI.

The electron transfer layer 50 may include a lanthanide metal and an alkali halide. Alternatively, the electron transfer layer 50 may include an alkali earth metal and an alkali halide. The constituent materials of the electron transfer layer 50 may react with each other to form a ternary compound. Alternatively, the constituent materials of the electron transfer layer 50 may be separated from each other.

According to an exemplary embodiment of the present invention, the electron transport layer (ETL) of the electron transfer layer 50 may include an organic material, and the electron injection layer (EIL) may include an alkali halide doped in a lanthanide metal or an alkaline earth metal. The electron injection layer (EIL) including the alkali halide doped in a lanthanide metal or an alkaline earth metal may increase electron injection speed. In the hole transfer layer (HTL) according to an exemplary embodiment of the present invention, hole transport speed may increase, for example, by doping the tellurium or telluride compound of a transition metal. Thus, electrons and holes may be coupled to each other relatively quickly in the light-emitting layer and the light-emission quality of the display device may increase.

In the light emitting-diode according to an exemplary embodiment of the present invention, the hole transfer layer 40 may include an organic material and tellurium or a telluride compound of a transition metal which is doped in the organic material. The organic material may include a compound represented by Chemical Formula 1 below.

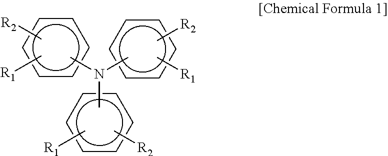

R₁ and R₂ may each be independently selected from a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₂-C₆₀ heteroaryl group, a substituted or unsubstituted monovalent non-aromatic condensed polycyclic group, or a substituted or unsubstituted monovalent non-aromatic hetero-condensed polycyclic group.

A doping concentration of the tellurium or the telluride compound of a transition metal may be in a range of from about 1 vol % to about 10 vol %. The tellurium or the telluride compound of a transition metal may be doped in the organic material. The organic material and the compound may form a charge transfer complex.

The volume ratio described according to an exemplary embodiment of the present invention may be measured, for example, based on a target volume in a thermal deposition process for doping. Thus, when doping the tellurium or the telluride compound of a transition metal in the organic material, a volume reduction amount of a tellurium target or a telluride compound target of the transition metal used in thermal deposition may be measured to draw the volume ratio.

According to an exemplary embodiment of the present invention, tellurium may be a material having a work function of about 4.95 eV, a band gap of about 0.45 eV, and a melting point of about 449° C. The tellurium may be thermally evaporated at a relatively low temperature due to a relatively low melting point and may increase a p-doping effect with a relatively small amount thereof due to, for example, the relatively small band gap. Further, the telluride compound of the transition metal may have an intrinsic p-type due to, for example, a relatively lower thermal evaporation temperature than other chalcogen compounds and a cation vacancy. The telluride compound of the transition metal may be used as a p-doping material.

However, the tellurium and the telluride compound of a transition metal may have a relatively high conductivity, for example, due to the relatively low band gap. The tellurium and the telluride compound of a transition metal may absorb light when a predetermined content or more is included. Accordingly, the content of the tellurium and the telluride compound of a transition metal in the hole transfer layer 40 may be included in a range of from about 1% vol to about 10 vol %. When the content of the tellurium and the telluride compound of a transition metal in the hole transfer layer 40 is less than about 1 vol %, the hole transfer layer 40 might not have a desired p-doping effect. When the content of the tellurium and the telluride compound of a transition metal in the hole transfer layer 40 exceeds about 10 vol %, the generated light may be absorbed and the light-emission efficiency may be decreased.

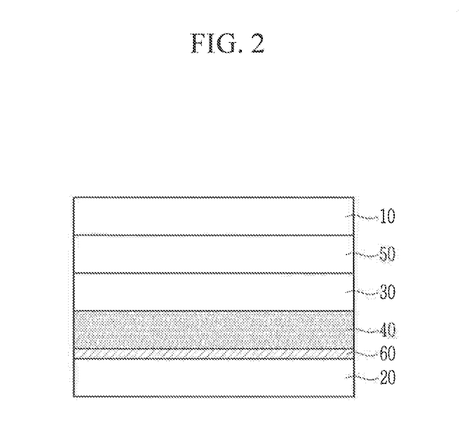

A light-emitting diode according to an exemplary embodiment of the present invention will be described in more detail with reference to FIGS. 2 to 4. FIGS. 2 to 4 are cross-sectional views illustrating a light-emitting diode according to an exemplary embodiment of the present invention. Referring to FIGS. 2 to 4, a light-emitting diode according to an exemplary embodiment of the present invention may include a first electrode 10, a second electrode 20, a light-emitting layer 30, a hole transfer layer 40, and a hole auxiliary layer 60. The first electrode 10 may at least partially overlap the second electrode 20. For example, the first electrode 10 may entirely overlap the second electrode 20. The light-emitting layer 30 may be disposed between the first electrode 10 and the second electrode. The hole transfer layer 40 may be disposed between the light-emitting layer 30 and the second electrode 20. The hole auxiliary layer 60 may be disposed between the hole transfer layer 40 and the light-emitting layer 30. Alternatively, the hole auxiliary layer 60 may be disposed between the hole transfer layer 40 and the second electrode 20. The hole auxiliary layer 60 may be disposed between the hole transfer layer 40 and the light-emitting layer 30, and between the hole transfer layer 40 and the second electrode 20. The hole auxiliary layer 60 may include tellurium or a telluride compound of a transition metal.

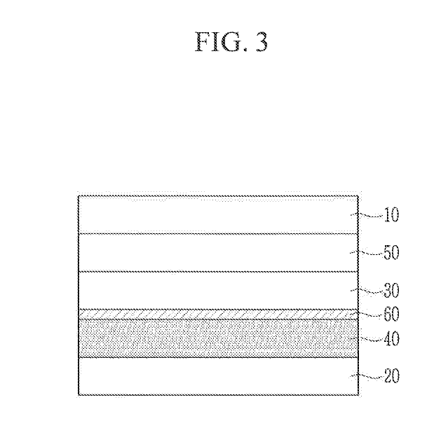

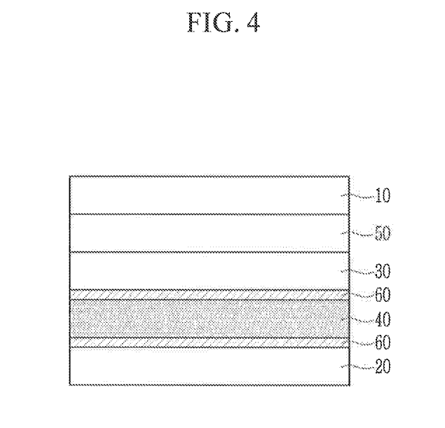

Referring to FIGS. 2 to 4, the hole auxiliary layer 60 may be positioned adjacent to the hole transfer layer 40. The hole auxiliary layer 60 may have a single layer form including tellurium or a telluride compound of a transition metal while being adjacent to the hole transfer layer 40. According to an exemplary embodiment of the present invention, referring to FIG. 2, the hole auxiliary layer 60 may be disposed between the hole transfer layer 40 and the second electrode 20. Referring to FIG. 3, the hole auxiliary layer 60 may be positioned between the hole transfer layer 40 and the light-emitting layer 30. Referring to FIG. 4, the hole auxiliary layers 60 may be positioned between the hole transfer layer 40 and the second electrode 20, and between the hole transfer layer 40 and the light-emitting layer 30.

According to an exemplary embodiment of the present invention, referring to FIGS. 2 to 4, the hole auxiliary layer 60 may be positioned on a separate layer from the hole transfer layer 40. Thus facilitation of an injection of the holes may be increased. The hole auxiliary layer 60 might not include an organic material. The hole auxiliary layer 60 may include tellurium or a telluride compound of a transition metal, or both the tellurium and the telluride compound of a transition metal. However, exemplary embodiments of the present invention are not limited thereto. For example, the hole auxiliary layer 60 may include an organic material and may have a form in which the tellurium or the telluride compound of a transition metal is doped in the organic material.

According to an exemplary embodiment of the present invention, the telluride of a transition metal included in the hole auxiliary layer 60 may be at least one selected from ZnTe, NiTe, PdTe, PtTe, CoTe, RhTe, IrTe, FeTe, RuTe, IrTe, FeTe, RuTe, OsTe, MnTe, TcTe, ReTe, Cu2Te, CuTe, Ag₂Te, AgTe, Au₂Te, Cr₂Te₃, Mo₂Te₃, W₂Te₃, V₂Te₃, Nb₂Te₃, Ta₂Te₃, TiTe₂, ZrTe₂, HfTe₂, Li₂Te, Na₂Te, K₂Te, Rb₂Te, Cs₂Te, BeTe, MgTe, CaTe, SrTe, BaTe, LaTe, CeTe, PrTe, NdTe, PmTe, EuTe, GdTe, TbTe, DyTe, HoTe, ErTe, TmTe, YbTe, Bi₂Te₃ or LuTe.

According to an exemplary embodiment of the present invention, referring to FIGS. 2 to 4, a thickness of the hole auxiliary layer 60 may be in a range of from about 5Ω to about 30Ω. Referring to FIG. 1, the tellurium or the telluride compound of a transition metal included as the material of the hole auxiliary layer 60 may have a relatively low band gap and a relatively high conductivity, and may absorb light relatively well. Accordingly, when the thickness of the hole auxiliary layer 60 is equal to or larger than about 30Ω, light may be absorbed in the hole auxiliary layer 60. Further, when the thickness of the hole auxiliary layer 60 is smaller than about 5Ω, the thickness may be too small, and the hole transportation might not be increased.

According to an exemplary embodiment of the present invention, the description of the first electrode 10, the second electrode 20, the light-emitting layer 30, and the electron transfer layer 50 may be substantially the same as described above. The detailed description of like constituent elements may be omitted below. According to an exemplary embodiment of the present invention, the hole transfer layer 40 may include an organic material which is not doped with the tellurium or telluride compound of a transition metal, in which the organic material may include a compound represented by Chemical Formula 1 below.

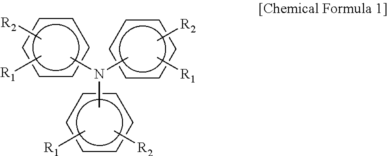

R₁ and R₂ may each independently be selected from a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₂-C₆₀ heteroaryl group, a substituted or unsubstituted monovalent non-aromatic condensed polycyclic group, or a substituted or unsubstituted monovalent non-aromatic hetero-condensed polycyclic group.

An effect of the light-emitting diode according to an exemplary embodiment of the present invention will be described in more detail below.

The light-emitting diodes of the Comparative Example and Examples 1 to 4 were manufactured under substantially the same conditions. However, the Comparative Example included only organic material in the hole injection layer of the hole transfer layer of the light-emitting diode, and in Examples 1 to 4, the organic material included in the hole injection layer of the hole transfer layer of the light-emitting diode was ZnTe-doped. Exemplary driving voltages and efficiency measurements are illustrated in Table 1.

TABLE 1

| | Driving | |
|---|---|---|
| Hole injection layer (HIL) | voltage (V) | Efficiency (Cd/A) |
| (Comparative Example 1) | 4.2 | 133.4 |
| Only organic material | | |
| (Example 1) ZnTe 2 vol % | 3.7 | 149 |
| doping | | |
| (Example 2) ZnTe 4 vol % | 3.6 | 149.6 |
| doping | | |
| (Example 3) ZnTe 6 vol % | 3.6 | 150.7 |
| doping | | |
| (Example 4) ZnTe 8 vol % | 3.6 | 150.5 |
| doping | | |

The light-emitting diodes of the Comparative Examples 2 to 5 and Examples 5 to 8 were manufactured under substantially the same conditions. However, the Comparative Examples 2 to 5 included CuI-doped organic material in the hole injection layer of the hole transfer layer of the light-emitting diode, and in Examples 5 to 8, the organic material included in the hole injection layer of the hole transfer layer of the light-emitting diode was Te-doped. Exemplary driving voltages and efficiency measurements are illustrated in Table 2.

TABLE 2

| | Driving | |
|---|---|---|
| Hole injection layer (HIL) | voltage (V) | Efficiency (Cd/A) |
| (Comparative Example 2) | 3.9 | 143.5 |
| CuI 2 vol % doping | | |
| (Comparative Example 3) | 3.8 | 145.7 |
| CuI 4 vol % doping | | |
| (Comparative Example 4) | 3.8 | 142.5 |
| CuI 6 vol % doping | | |
| (Comparative Example 5) | 3.8 | 142.2 |
| CuI 8 vol % doping | | |
| (Example 5) Te 2 vol % | 3.6 | 145 |
| doping | | |
| (Example 6) Te 4 vol % | 3.6 | 147.2 |
| doping | | |
| (Example 7) Te 6 vol % | 3.6 | 151 |
| doping | | |
| (Example 8) Te 8 vol % | 3.6 | 152.4 |
| doping | | |

Referring to Table 1, compared to using only the organic material as the hole injection layer (HIL), when doping a telluride compound of a transition metal, such as ZnTe, the driving voltage (V) may be reduced and the efficiency (Cd/A) may be increased.

Further, a difference between the reduction of the driving voltage (V) and the efficiency (Cd/A) according to an increase in content of ZnTe is relatively small. When the content of ZnTe is increased, a relatively large amount of light is absorbed by ZnTe. Thus, a content of ZnTe may be smaller than about 10 vol %.

Referring to Table 2, compared with Comparative Examples 2 to 5 of CuI doping, the efficiency of Examples 5 to 8 of Te doping is increased. The driving voltage (V) in Examples 5 to 8 is decreased as compared with Comparative Examples 2 to 5.

Thus, referring to Tables 1 and 2, in a light-emitting diode, when doping a telluride compound of a transition metal (Examples 1 to 4) or tellurium (Examples 5 to 8), the driving voltage (V) may be reduced and the efficiency (Cd/A) may be increased as compared with a case of including only an organic material (Comparative Example 1) or doping a halide compound (Comparative Examples 2 to 5) such as CuI.

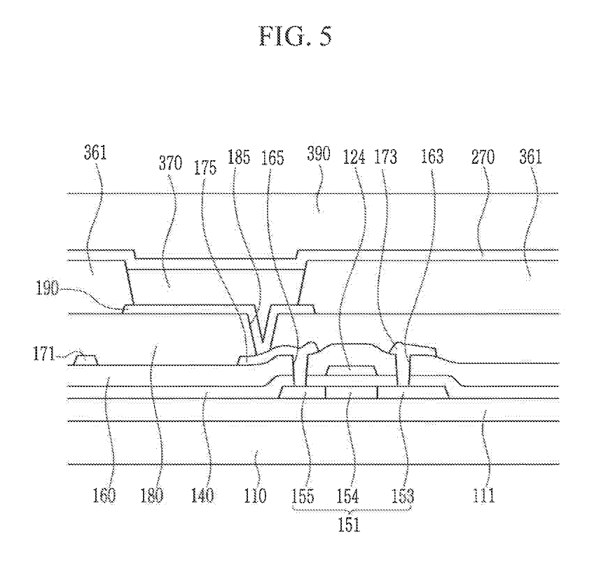

A display device according to an exemplary embodiment of the present invention will be described in more detail with reference to FIG. 5. FIG. 5 is a cross-sectional view illustrating a display device according to an exemplary embodiment of the present invention.

Referring to FIG. 5, a blocking layer 111 may be disposed on a substrate 110. The blocking layer 111 may include silicon oxide, or silicon nitride.

A semiconductor layer 151 may be disposed on the blocking layer 111. The semiconductor layer 151 may include a source region 153, a drain region 155, and a channel region 154. The source region 153 and the drain region 155 may be doped with p-type impurities. The channel region 154 may be disposed between the source region 153 and the drain region 155.

A gate insulating layer 140 may be disposed on the semiconductor layer 151 and the blocking layer 111. The gate insulating layer 140 may include silicon oxide or silicon nitride. A control electrode 124 may at least partially overlap the channel region 154 of the semiconductor layer 151. The control electrode 124 may be disposed on the gate insulating layer 140.

An interlayer insulating layer 160 may be disposed on the control electrode 124 and the gate insulating layer 140. The interlayer insulating layer 160 may include a first contact hole 165 and a second contact hole 163.

A data conductor including a data line 171, an input electrode 173 and an output electrode 175 may be positioned on the interlayer insulating layer 160.

The output electrode 175 may be connected to the drain region 155, for example, through the first contact hole 165. The input electrode 173 may be connected to the source region 153, for example, through the second contact hole 163.

A passivation layer 180 may be disposed on the data conductor. The passivation layer 180 may be disposed on the interlayer insulating layer 160. The passivation layer 180 may include a contact hole 185.

A pixel electrode 190 may be disposed on the passivation layer 180. The pixel electrode 190 may be connected to the output electrode 175, for example, through the contact hole 185. A partition wall 361 may be disposed on the passivation layer 180. A light-emitting diode layer 370 may at least partially overlap the pixel electrode 190. A common electrode 270 may at least partially overlap the light-emitting diode layer 370. The light-emitting diode may include the pixel electrode 190, the light-emitting diode layer 370 and the common electrode 270.

The pixel electrode 190 may be an anode as a hole injection electrode. The pixel electrode 190 may correspond to the second electrode 20 as described in FIGS. 1 to 4. The common electrode 270 may be a cathode as an electron injection electrode. The common electrode 270 may correspond to the first electrode 10 as described in FIGS. 1 to 4. However, exemplary embodiments of the present invention are not limited thereto. For example, according to a driving method of the display device, the pixel electrode 190 may be a cathode, and the common electrode 270 may be an anode.

The light-emitting diode layer 370 may include the light-emitting layer 30, the electron transfer layer 50, and the hole transfer layer 40 as described with reference to FIG. 1. Alternatively, the light-emitting diode layer may include the light-emitting layer 30, the electron transfer layer 50, the hole auxiliary layer 60, or the like as described with reference to FIGS. 2 to 4.

An encapsulation layer 390 may be positioned to at least partially overlap the common electrode 270. The encapsulation layer 390 may include an organic material or an inorganic material. Alternatively, the encapsulation layer 390 may be formed by alternately laminating organic materials and inorganic materials. The encapsulation layer 390 may protect the display device from external moisture, heat, and other pollutions.

The structure of the display device described above is exemplified, and it is apparent that the light-emitting diode according to exemplary embodiments of the present invention may be applied to display devices having different structures.

While exemplary embodiments of the present invention has been described herein, it is to be understood that the present invention is not limited to the disclosed exemplary embodiments, but, on the contrary, is intended to cover various modifications and equivalent arrangements included within the spirit and scope of the present invention.

What is claimed is:

1. A light-emitting diode, comprising:
a first electrode;
a second electrode;
a light-emitting layer disposed between the first electrode and the second electrode; and
a hole transfer layer disposed between the light-emitting layer and the second electrode,
wherein the hole transfer layer includes an organic material and at least one of tellurium or a telluride compound of a transition metal is doped in the organic material included in the hole transfer layer.

2. The light-emitting diode of claim 1, wherein:
in the hole transfer layer, a doped content of the at least one of the tellurium or the telluride compound of the transition metal is in a range of from about 1 vol % to about 10 vol %.

3. The light-emitting diode of claim 1, wherein:
the telluride compound of the transition metal is at least one selected from ZnTe, NiTe, PdTe, PtTe, CoTe, RhTe, IrTe, FeTe, RuTe, IrTe, FeTe, RuTe, OsTe, MnTe, TcTe, ReTe, Cu2Te, CuTe, Ag₂Te, AgTe, Au₂Te, Cr₂Te₃, Mo₂Te₃, W₂Te₃, V₂Te₃, Nb₂Te₃, Ta₂Te₃, TiTe₂, ZrTe₂, HfTe₂, Li₂Te, Na₂Te, K₂Te, Rb₂Te, Cs₂Te, BeTe, MgTe, CaTe, SrTe, BaTe, LaTe, CeTe, PrTe, NdTe, PmTe, EuTe, GdTe, TbTe, DyTe, HoTe, ErTe, TmTe, YbTe, Bi₂Te₃ or LuTe.

4. The light-emitting diode of claim 1, wherein:
the organic material of the hole transfer layer includes a compound represented by Chemical Formula 1 below: 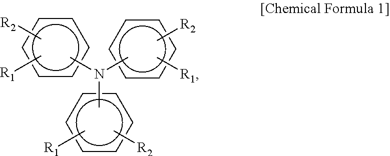
wherein R₁ and R₂ are each independently selected from a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₂-C₆₀ heteroaryl group, a substituted or unsubstituted monovalent non-aromatic condensed polycyclic group, or a substituted or unsubstituted monovalent non-aromatic hetero-condensed polycyclic group.

5. The light-emitting diode of claim 1, further comprising:
an electron transfer layer disposed between the first electrode and the light-emitting layer,
wherein the electron transport layer includes an alkali halide doped in a lanthanide metal or an alkaline earth metal.

6. The light-emitting diode of claim 5, wherein:
the lanthanide metal is at least one selected from La, Ce, Pr, Nd, Pm, Sm, Eu, Gd, Tb, Dy, Ho, Er, Tm, Yb or Lu;
the alkali earth metal is at least one selected from Mg, Ca, Sr, Ba or Ra; and
the alkali halide is at least one selected from LiCl, NaCl, KCl, RbCl, CsCl, FrCl, LiBr, NaBr, KBr, RbBr, CsBr, FrBr, LiI, NaI, KI, RbI, CsI or FrI.

7. The light-emitting diode of claim 5 wherein:
the electron transfer layer includes an electron transport layer and an electron injection layer;
the electron transport layer is disposed between the light-emitting layer and the first electrode, and the electron injection layer is disposed between the electron transport layer and the first electrode; and
the electron transport layer includes an alkali halide doped in a lanthanide metal or an alkaline earth metal.

8. The light-emitting diode of claim 1, wherein:
the hole transfer layer includes a hole injection layer and a hole transport layer; and
the hole injection layer is disposed between the second electrode and the hole transport layer, and the hole transport layer is disposed between the hole injection layer and the light-emitting layer.

9. A light-emitting diode, comprising:
a first electrode;
a second electrode overlapping the first electrode;
a light-emitting layer disposed between the first electrode and the second electrode;
a hole transfer layer disposed between the light-emitting layer and the second electrode; and
a hole auxiliary layer disposed in at least one of between the hole transfer layer and the light-emitting layer or between the hole transfer layer and the second electrode,
wherein the hole auxiliary layer includes at least one of tellurium or a telluride compound of a transition metal.

10. The light-emitting diode of claim 9, wherein:
a thickness of the hole auxiliary layer is in a range of from about 5Ω to about 30Ω.

11. The light-emitting diode of claim 9, wherein:
the telluride compound of the transition metal is at least one selected from ZnTe, NiTe, PdTe, PtTe, CoTe, RhTe, IrTe, FeTe, RuTe, IrTe, FeTe, RuTe, OsTe, MnTe, TcTe, ReTe, Cu2Te, CuTe, Ag₂Te, AgTe, Au₂Te, Cr₂Te₃, Mo₂Te₃, W₂Te₃, V₂Te₃, Nb₂Te₃, Ta₂Te₃, TiTe₂, ZrTe₂, HfTe₂, Li₂Te, Na₂Te, K₂Te, Rb₂Te, Cs₂Te, BeTe, MgTe, CaTe, SrTe, BaTe, LaTe, CeTe, PrTe, NdTe, PmTe, EuTe, GdTe, TbTe, DyTe, HoTe, ErTe, TmTe, YbTe, Bi₂Te₃ or LuTe.

12. The light-emitting diode of claim 9, further comprising:
an electron transfer layer disposed between the first electrode and the light-emitting layer,
wherein the electron transfer layer includes an alkali halide doped in a lanthanide metal or an alkaline earth metal.

13. The light-emitting diode of claim 12, wherein:
the lanthanide metal is at least one selected from La, Ce, Pr, Nd, Pm, Sm, Eu, Gd, Tb, Dy, Ho, Er, Tm, Yb or Lu;
the alkali earth metal is at least one selected from Mg, Ca, Sr, Ba or Ra; and
the alkali halide is at least one selected from LiCl, NaCl, KCl, RbCl, CsCl, FrCl, LiBr, NaBr, KBr, RbBr, CsBr, FrBr, LiI, NaI, KI, RbI, CsI or FrI.

14. The light-emitting diode of claim 12, wherein:
the electron transfer layer includes an electron transport layer and an electron injection layer;
the electron transport layer is disposed between the light-emitting layer and the first electrode, and the electron injection layer is disposed between the electron transport layer and the first electrode; and
the electron transport layer includes an alkali halide doped in a lanthanide metal or an alkaline earth metal.

15. The light-emitting diode of claim 9, wherein:
the hole auxiliary layer does not include an organic material.

16. The light-emitting diode of claim 9, wherein:
the hole auxiliary layers are disposed between the hole transfer layer and the light-emitting layer, and
the hole auxiliary layers are disposed between the hole transfer layer and the second electrode.

17. A light-emitting diode, comprising:
a first electrode;
a second electrode overlapping the first electrode;
a light-emitting layer disposed between the first electrode and the second electrode; and
a hole transfer layer disposed between the light-emitting layer and the second electrode,
wherein the hole transfer layer includes an inorganic material and at least one of tellurium or a telluride compound of a transition metal is doped in the inorganic material included in the hole transfer layer.

18. The light-emitting diode of claim 17, wherein:
the inorganic material includes a material having a band gap of about 3.2 eV or more.

19. The light-emitting diode of claim 17, wherein:
the inorganic material is at least one of NaI, KI, RbI, CsI, MgI₂, CaI₂, SrI₂, or BaI.

20. The light-emitting diode of claim 19, wherein:
the tellurium or the telluride compound of the transition metal is at least one selected from Te, ZnTe, or CoTe; and
a doped content of at least one of the tellurium or the telluride compound of the transition metal is in a range of from about 1 vol % to about 50 vol %.
